(19) United States
(12) Patent Application Publication
(10) Pub. No.: US 2025/0268085 A1
(43) Pub. Date: Aug. 21, 2025

(54) DISPLAY DEVICE

(71) Applicant: Samsung Display Co., Ltd., Yongin-si (KR)

(72) Inventors: SANGDUK LEE, Yongin-si (KR); HOIKWAN LEE, Yongin-si (KR)

(21) Appl. No.: 18/934,687

(22) Filed: Nov. 1, 2024

(30) Foreign Application Priority Data
Feb. 20, 2024 (KR) 10-2024-0024513

(51) Int. Cl. H10K 59/80

(52) U.S. Cl. CPC H10K 59/8792

(57) ABSTRACT

A display device includes a display panel, an anti-reflective layer disposed on the display panel, a support film having a frame shape when viewed on a plane, and disposed on an edge portion of the anti-reflective layer, and a coated window disposed on an upper surface of the support film and an upper surface of the anti-reflective layer.

### DISPLAY DEVICE

This application claims priority to Korean Patent Application No. 10-2024-0024513, filed on Feb. 20, 2024, and all the benefits accruing therefrom under 35 U.S.C. § 119, the content of which in its entirety is hereby incorporated by reference.

### BACKGROUND

### 1. Field

The present disclosure herein relates to a display device, and more particularly to a display device having an improved manufacturing processability.

### 2. Description of Related Art

A display device that provides images to a user, such as a television, a monitor, a smartphone, and a tablet computer, includes a display panel that displays the image. Various display panels such as liquid crystal display panels, organic light-emitting display panels, electro-wetting display panels, and electrophoretic display panels are being developed as display panels. In addition, the display device may include a window for protecting the display panel.

### SUMMARY

The invention provides a display device with improved manufacturing processability.

An embodiment of the invention provides a display device including a display panel, an anti-reflective layer disposed on the display panel, a support film having a frame shape when viewed on a plane and disposed on an edge portion of the anti-reflective layer, and a coated window disposed on an upper surface of the support film and an upper surface of the anti-reflective layer.

In an embodiment, a display device includes a display panel in which a display region and a non-display region surrounding the display region are defined, an anti-reflective layer disposed on the display panel, a support film in which an opening is defined when viewed on a plane, and which is disposed on an edge portion of the anti-reflective layer, a light-shielding pattern covering an upper surface of the support film and an inner side surface of the support film defining the opening, and a coated window disposed on the upper surface of the support film and an upper surface of the anti-reflective layer via the opening.

### BRIEF DESCRIPTION OF THE FIGURES

The accompanying drawings are included to provide a further understanding of the invention, and are incorporated in and constitute a part of this specification. The drawings illustrate embodiments of the invention and, together with the description, serve to explain principles of the invention. In the drawings:

FIG. 1 is a perspective view of a display device, according to an embodiment;

FIG. 2A is an exploded perspective view of a display device, according to an embodiment;

FIG. 2B is an exploded perspective view of a display device, according to an embodiment;

FIG. 3 is a perspective view of a window support layer illustrated in FIGS. 2A and 2B, according to an embodiment;

FIG. 4 is a plan view of a display panel illustrated in FIG. 3, according to an embodiment;

FIG. 5 is a plan view of a touch sensing panel illustrated in FIGS. 2A and 2B, according to an embodiment;

FIG. 6A is a cross-sectional view of a display device corresponding to line I-I′ illustrated in FIG. 2B, according to an embodiment;

FIG. 6B is a cross-sectional view of a display device corresponding to line II-II′ illustrated in FIG. 2B, according to an embodiment;

FIG. 7A is a cross-sectional view of a display device, according to an embodiment;

FIG. 7B is a cross-sectional view of a display device, according to an embodiment;

FIG. 8A is an exploded perspective view of a display device including a display panel, according to an embodiment;

FIG. 8B is an exploded perspective view of a display device including a display panel, according to an embodiment;

FIG. 9A is a cross-sectional view of a display device corresponding to line III-III′ illustrated in FIG. 8B, according to an embodiment;

FIG. 9B is a cross-sectional view of a display device corresponding to line IV-IV′ illustrated in FIG. 8B, according to an embodiment;

FIG. 10A is a cross-sectional view of a display device including a window support layer, according to an embodiment; and

FIG. 10B is a cross-section view of a display device including a window support layer, according to an embodiment.

### DETAILED DESCRIPTION

Advantages and features of the invention, and a method for achieving the same will become clear by referring to embodiments described in detail below with the accompanying drawings. However, the invention is not limited to the embodiments disclosed below and may be implemented in various different forms. The embodiments disclosed herein only serve to ensure that the disclosure is complete, and to fully inform those skilled in the art of the invention and of the scope of the invention. The same reference numerals or symbols refer to the same components throughout the specification.

When an element or layer is referred to as “on” another element or layer, it refers not only to being directly on top of the other element or layer, but also to interposing a third element or layer therebetween. On the other hand, when an element or layer is referred to as “directly on” another element or layer, it indicates that there is no interposed element or layer therebetween. “And/or” includes each and every combination of one or more of the mentioned items.

A spatially relative term such as “below”, “beneath”, “lower”, “above”, or “upper” may be used so as to easily describe the correlation between a single element or component and another element or component, as shown in the drawing. The spatially relative term should be understood as a term that includes different directions of the element during use or operation in addition to the direction shown in the drawing. The same reference numerals or symbols refer to the same components throughout the specification.

Although first, second, etc. are used to describe various elements, components, and/or sections, these elements, components, and/or sections are, of course, not limited by these terms. These terms are merely used in order to distinguish one element, component, or section from another element, component, or section. Accordingly, it should be appreciated that a first element, first element, or first section to be mentioned below may also be, of course, a second element, second element, or second section within the technical spirit of the inventive concept.

Embodiments to be described herein will be described with reference to plan and cross-sectional views, which are ideal schematic diagrams of the invention. Accordingly, a form of the illustration may be modified depending on manufacturing technology and/or acceptable tolerance. Accordingly, the invention is not limited to a specific form shown, but may also include a change in the form produced according to a manufacturing process. Accordingly, regions illustrated in the drawings have schematic properties, and shapes of the regions illustrated in the drawings are intended to illustrate specific shapes of the regions of an element, and are not intended to limit the scope of the invention.

Hereinafter, the invention will be described in more detail with reference to the accompanying drawings, according to one or more embodiments.

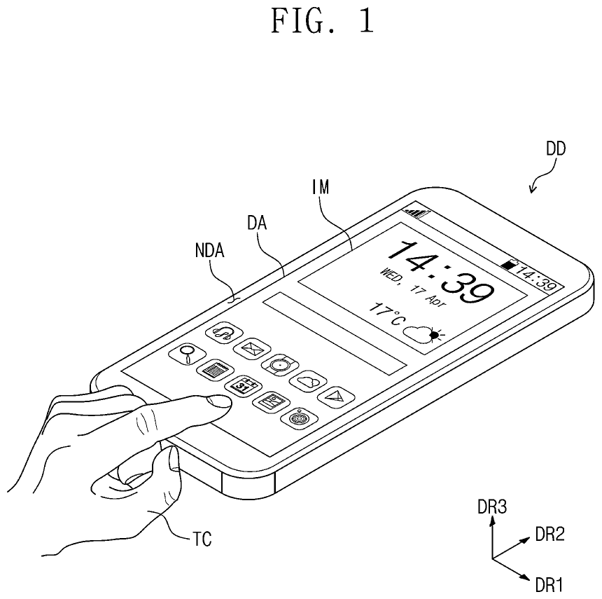

FIG. 1 is a perspective view of a display device, according to an embodiment.

In an embodiment and referring to FIG. 1, a portable terminal is illustrated as an example of a display device DD, where the portable terminal may include a tablet computer, a smartphone, a personal digital assistant (PDA), a portable multimedia player (PMP), a game console, a wrist-watch-type electronic device, or the like, but the invention is not limited thereto.

According to various embodiments, the display device may be used not only in a large-sized electronic device such as a television, or a billboard, but also in a small- and medium-sized electronic device such as a personal computer, a notebook computer, a car navigation unit, or a camera. These are only suggested as examples, and other electronic devices may be also adopted as long as not deviating from the concept of the invention.

In an embodiment, the display device DD may be flexible. The expression, “flexible”, means characteristics of being capable of being bent, and may include all structures from a structure which may be completely bent to a structure which may be bent to a level of several nanometers, inclusive. For example, a flexible display device DD may include a curved display device, a foldable display device, a slidable display device, or a rollable display device. However, the display device DD is not limited thereto, and the display device DD may be rigid.

In an embodiment and as illustrated in FIG. 1, a display surface on which an image IM is displayed is directed parallel to a plane defined by a first direction DR1 and a second direction DR2. The display device DD includes a plurality of regions disposed on the display surface, where the display surface includes a display region DA on which the image IM is displayed, and a non-display region NDA which is disposed adjacent to the display region DA. The non-display region NDA may be referred to as a bezel region. For example, the display region DA may have a tetragonal shape. The non-display region NDA may surround the display region DA. In addition, although not shown, for example, the display device DD may include a partially curved shape. As a result, one region of the display region DA may have a curved shape.

A front surface (or upper surface) and a rear surface (or lower surface) of each member that constitutes the display device DD may be opposed to each other in a third direction DR3, and the normal direction of each of the front surface and the rear surface may be directed substantially parallel to the third direction DR3. A distance between the front surface and the rear surface defined along the third direction DR3 may correspond to a thickness of the display device DD (or unit).

In the present specification, the expression, “on a plane” may be defined as a state of being viewed in the third direction DR3. In the present specification, the expression, “on a cross-section” may be defined as a state of being viewed in the first direction DR1 or the second direction DR2. Meanwhile, directions indicated by the directions DR1, DR2, and DR3 are relative concepts, and may be changed to include other directions. In the present specification, the expression, “A overlaps B” may mean that A overlaps B on one plane as long as there is no special definition.

In an embodiment, the front surface (or upper surface, or first surface) and the rear surface (or lower surface, or second surface) of each member are defined with respect to a direction in which the image IM is displayed. However, the directions indicated by the directions DR1, DR2, and DR3 are relative concepts, and may be changed to include other directions. Hereinafter, the first to third directions are respectively the directions DR1, DR2, and DR3, and refer to the same reference numerals or symbols.

In an embodiment, the display device DD may sense a user's touch input TC applied from the outside. The user's touch input TC may include an external input having various forms such as a part of a user's body, light, heat, or pressure. In an embodiment, the user's input is described assuming a user's hand being applied on the front surface, but this is merely an example, and as described above, the user's input TC may be supplied having various forms. In addition, the display device DD may sense the user's input being applied on a side surface or the rear surface of the display device DD according to a structure of the display device DD, and is not limited to any one embodiment.

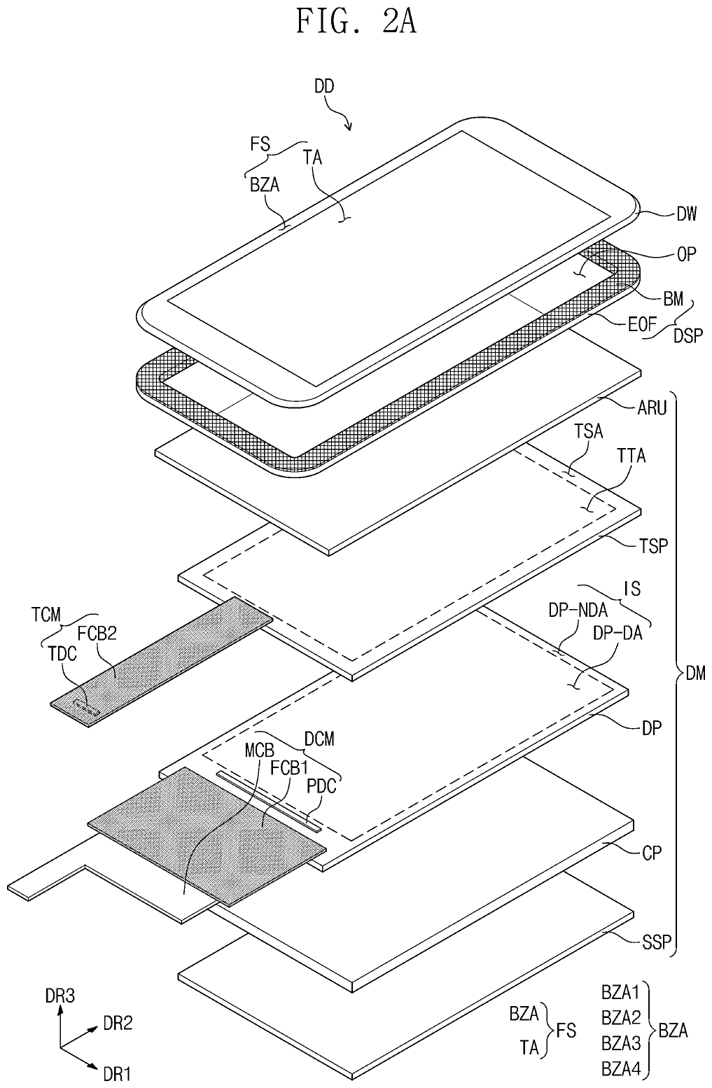

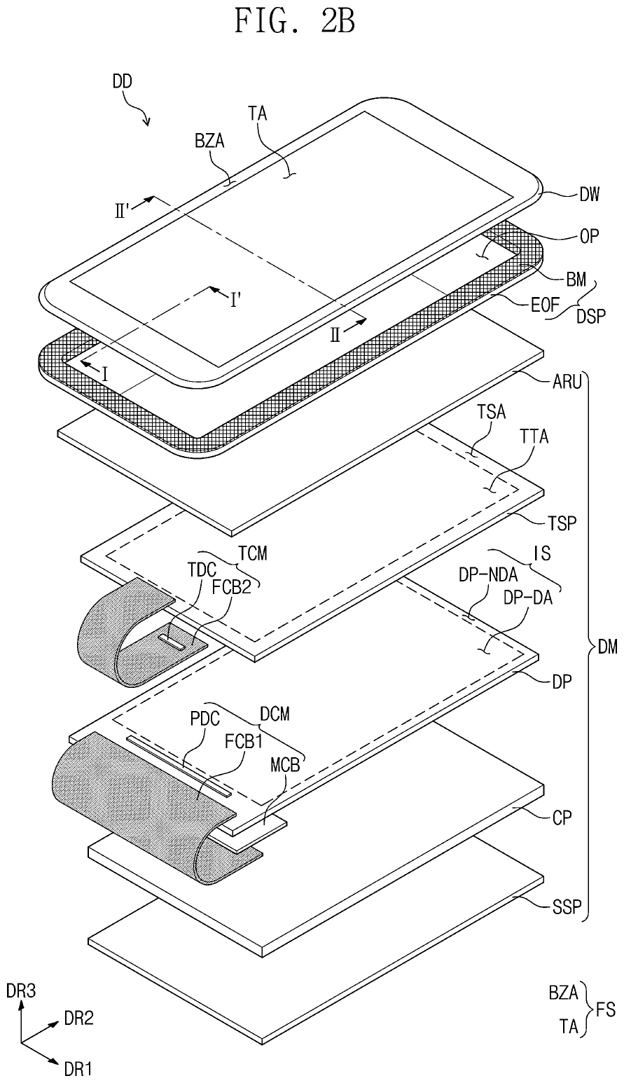

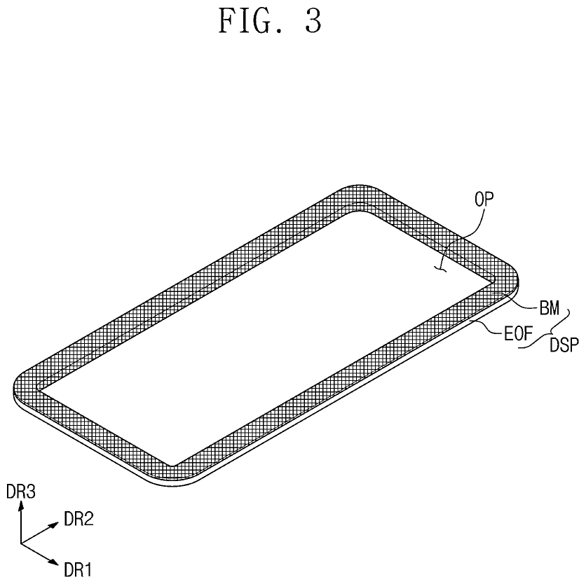

FIGS. 2A and 2B are exploded perspective views of a display device, according to an embodiment. FIG. 3 is a perspective view of a window support layer illustrated in FIGS. 2A and 2B, according to an embodiment.

In an embodiment and referring to FIG. 2A and FIG. 2B, FIG. 2A shows an exploded perspective view of a display device DD in which a first circuit board FCB1 (or first flexible board) and a second flexible circuit board FCB2 (or second flexible board) are not bent, and FIG. 2B is an exploded perspective view of the display device DD in which the first flexible circuit board FCB1 and the second flexible circuit board FCB2 are bent.

In an embodiment and referring to FIGS. 2A and 2B, the display device DD may include a coated window DW, a window support layer DSP, and a display module DM. The coated window DW may provide a front surface FS of the display device DD, where the front surface FS of the coated window DW may include a transmission region TA and a bezel region BZA. The transmission region TA of the coated window DW may be an optically transparent region. The coated window DW may transmit an image IM provided by the display panel DP through the transmission region TA, and a user may view the corresponding image IM (see FIG. 1).

The bezel region BZA may be disposed adjacent to the transmission region TA. A shape of the transmission region TA may be substantially defined by the bezel region BZA. For example, the bezel region BZA may be disposed outside of the transmission region TA to surround the transmission region TA. However, this is illustrated only as an example, and the bezel region BZA may be disposed adjacent to only one side of the transmission region TA, or may be omitted. In addition, the bezel region BZA may be disposed on a side surface of the display device DD and not on the front surface thereof.

In an embodiment, the coated window DW may include an optically transparent insulating material, and may include a curable resin material. The coated window DW may have a single-layered or multi-layered structure and the coated window DW may be formed by applying the resin material on a support film EOF and curing the same. The display device DD including the coated window DW, according to an embodiment, may simplify a process of manufacturing the display device DD, and may reduce a cost by omitting a lamination process of attaching a glass window to a panel.

In an embodiment and referring to FIGS. 2A to 3, the window support layer DSP may be disposed between the coated window DW and the display module DM. The window support layer DSP may have a tetragonal frame shape having short sides extending in the first direction DR1 and long sides extending in the second direction DR2. The window support layer DSP may overlap the bezel region BZA. The window support layer DSP may not overlap the transmission region TA.

In an embodiment, an opening OP may be defined by the window support layer DSP, where the opening OP may overlap the transmission region TA.

In an embodiment, the window support layer DSP may include the support film EOF and a light-shielding pattern BM disposed on the support film EOF. The support film EOF may have a tetragonal frame shape and may be an optically transparent film. The support film EOF may include a material having no color and being transparent to have excellent optical characteristics. For example, the support film EOF may be a polyimide (PI) film, or a film including polyethyleneterephthalate (PET), or the like. However, a material of the support film EOF is not limited thereto, and the support film EOF may have various materials according to need.

In an embodiment, the light-shielding pattern BM may be disposed on an upper surface of the support film EOF. The light-shielding pattern BM may be disposed on an inner surface of the support film EOF defining the opening OP. The light-shielding pattern BM may be a black resin that does not transmit light. The light-shielding pattern BM may be disposed to overlap a non-display region DP-NDA of the display panel DP. The light-shielding pattern BM may be disposed to overlap the bezel region BZA of the coated window DW.

In an embodiment and referring to FIGS. 2A and 2B, the display module DM may be disposed on a rear surface of the coated window DW to generate an image. In addition, the display module DM may sense the user's input TC (see FIG. 1).

In an embodiment, the display module DM providing a flat display surface is illustrated, but the shape of the display module DM may be changed. Edges, of the display module DM, facing in the first direction DR1 may be bent from portions close to the center to provide a curved surface.

In an embodiment, the display module DM may include an anti-reflective layer ARU, a touch sensing panel TSP, a display panel DP, a protective panel CP, a support panel SSP, a driving control module DCM, and a touch control unit TCM.

In an embodiment, the anti-reflective layer ARU may be disposed on the display panel DP, and may overlap the display region DP-DA. The anti-reflective layer ARU may be disposed between the display panel DP and the support film EOF. The anti-reflective layer ARU may reduce reflectance of light incident from the outside and may include at least one of a retarder, a polarizer, a polarizing film, or a polarizing filter. The anti-reflective layer ARU may be attached to the display panel DP through an adhesive layer. However, a type of the anti-reflective layer ARU is an example, and is not limited thereto. For example, the anti-reflective layer ARU may include a color filter, and in this case, the adhesive layer may be omitted.

In an embodiment, the display panel DP may be disposed between the coated window DW and the support panel SSP. The display panel DP may display an image in response to an electrical signal. The display panel DP, according to an embodiment, may be a light-emitting display panel, but is not specially limited thereto. For example, the display panel DP may be an organic light-emitting display panel, an inorganic light-emitting display panel, an organic-inorganic display panel, or a quantum dot light-emitting display panel. A light-emitting layer of the organic light-emitting display panel may include an organic light-emitting material, and a light-emitting layer of the inorganic light-emitting display panel may include an inorganic light-emitting material. A light-emitting layer of the organic-inorganic light-emitting display panel may include an organic-inorganic light-emitting material. A light-emitting layer of the quantum dot light-emitting display panel may include quantum dots or a quantum rod.

In an embodiment, the image IM (see FIG. 1) provided by the display device DD may be displayed on a front surface IS of the display panel DP. The front surface IS of the display panel DP may include the display region DP-DA and the non-display region DP-NDA. In this embodiment, the display region DP-DA may correspond to the display region DA in FIG. 1, and the non-display region DP-NDA may correspond to the non-display region NDA in FIG. 1.

In an embodiment, the display region DP-DA may be a region which is activated in response to an electrical signal and on which an image is displayed. According to an embodiment, the display region DP-DA of the display panel DP may correspond to the transmission region TA of the coated window DW. In the present specification, the expression, “a region/portion corresponds to another region/portion” means “the region/portion overlaps the other region/portion”, and is not limited to that the region/portion and the other region/portion have the same area and/or the shape.

In an embodiment, the non-display region DP-NDA may be disposed adjacent to the outside of the display region DP-DA. For example, the non-display region DP-NDA may surround the display region DP-DA. However, an embodiment is not limited thereto, and the non-display region DP-NDA may be defined in various shapes.

In an embodiment, the non-display region DP-NDA may be a region in which a driving circuit or driving line for driving elements disposed in the display region DP-DA, various signal lines that supply electrical signals, pad, and the like are disposed. The non-display region DP-NDA of the display panel DP may correspond to the bezel region BZA of the coated window DW. The bezel region BZA may prevent configurations of the display panel DP disposed in the non-display region DP-NDA from being viewed from the outside.

In an embodiment, the driving control module DCM may include a main circuit board MCB (or driving circuit board), a first circuit board FCB1, and a panel driving circuit PDC. The first circuit board FCB1 may be connected to an end portion of the display panel DP to electrically connect the main circuit board MCB and the display panel DP.

In an embodiment, the panel driving circuit PDC may be disposed on the non-display region DP-NDA of the display panel DP and may be realized as an integrated circuit. Although not shown separately, a plurality of active elements and passive elements may be mounted on the main circuit board MCB. The main circuit board MCB may be a rigid circuit board or a flexible circuit board, and the first circuit board FCB1 may be a flexible circuit board. The main circuit board MCB may be placed on a rear surface of the display panel DP.

In an embodiment, the first circuit board FCB1 may be disposed on the non-display region NDA of the display panel DP and may be bendable. The first circuit board FCB1 may be connected to an end portion of the display panel DP to electrically connect the main circuit board MCB and the display panel DP. The first circuit board FCB1 may be bent such that one end thereof is disposed on the front surface of the display panel DP, and the other end thereof is disposed on the rear surface of the display panel DP. The first circuit board FCB1 may be bent so that the one end thereof is placed on the rear surface of the display panel DP. The other end of the first circuit board FCB1 may be opposed to the rear surface of the non-display region NDA in the third direction DR3. The main circuit board MCB may be placed on the rear surface of the display panel DP.

In an embodiment, the touch sensing panel TSP may be disposed between the display panel DP and the anti-reflective layer ARU, and may be connected to the second circuit board FCB2. The touch sensing panel TSP may acquire coordination information of the user's input TC (see FIG. 1). The touch sensing panel TSP may sense various forms of inputs supplied from the outside of the display device DD. In an embodiment, the touch sensing panel TSP may sense an input generated by a user's body, but the invention is not limited thereto. For example, the touch sensing panel TSP may sense external inputs, having various forms, such as light, heat, or pressure. In addition, the touch sensing panel TSP may sense not only an input in contact with a sensing surface, but also an input proximate to the sensing surface.

For example, in an embodiment, the touch sensing panel TSP may be a capacitive touch panel, an electromagnetic induction-type touch panel, or the like. This touch sensing panel TSP may include a base layer, sensing electrodes, and signal lines connected to the sensing electrodes.

In an embodiment, the touch control unit TCM may include the second circuit board FCB2 and a touch driving circuit TDC. The second circuit board FCB2 may electrically connect the main circuit board MCB and the touch sensing panel TSP, and the touch driving circuit TDC may be mounted on the second circuit board FCB2. The second circuit board FCB2 may be bendable like the first circuit board FCB1. The second circuit board FCB2 may electrically connect the main circuit board MCB and the touch sensing panel TSP. The touch driving circuit TDC may be realized as an integrated circuit. The second circuit board FCB2 may be a flexible circuit board.

In an embodiment, the protective panel CP may be disposed on the rear surface of the display panel DP to protect the display panel DP from an impact. The protective panel CP may include a plastic film as a base layer. The protective panel CP may include a single-layered or multi-layered structure.

In an embodiment, the support panel SSP may be disposed on a rear surface of the protective panel CP to support the display panel DP and the protective panel CP, where the support panel SSP may be a metal plate having a rigidity of at least a predetermined standard. The support panel SSP may be a stainless-steel plate. The support panel SSP may have a black color so as to block external light incident on the display panel DP.

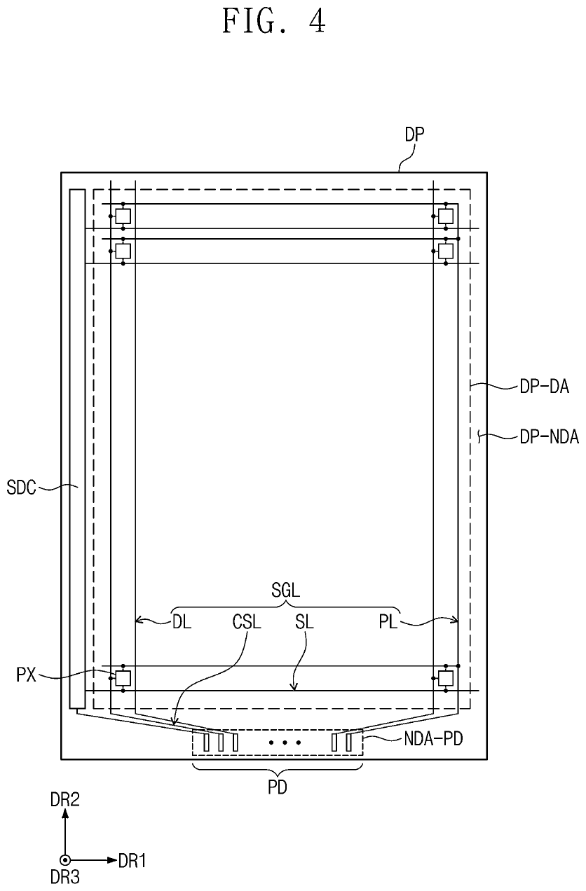

FIG. 4 is a plan view of the display panel illustrated in FIG. 3, according to an embodiment.

FIG. 4 illustrates a signal circuit view, according to an embodiment. In addition, some components are omitted in FIG. 4 for convenience of description.

In an embodiment and referring to FIG. 4, a display panel DP may include a display region DP-DA and a non-display region DP-NDA disposed on a plane. In an embodiment, the non-display region DP-NDA may be defined along an edge portion of the display region DP-DA. The display region DP-DA and the non-display region DP-NDA of the display panel DP may respectively correspond to the display region DA and the non-display region NDA of the display device DD illustrated in FIG. 1.

In an embodiment, the display panel DP may include a scan driving circuit SDC, a plurality of signal lines SGL (hereinafter, signal lines), a plurality of signal pads PD (hereinafter, signal pads), and a plurality of pixels PX (hereinafter, pixels). The pixels PX are disposed in the display region DP-DA and each of the pixels PX may include an organic light-emitting diode and a pixel driving circuit connected thereto.

In an embodiment, the scan driving circuit SDC generates a plurality of scan signals (hereinafter, scan signals), and sequentially outputs the scan signals to a plurality of scan lines SL (hereinafter, scan lines) to be described later. The scan driving circuit SDC may further output another control signal to driving circuits of the pixels PX.

In an embodiment, the scan driving circuit SDC may include a plurality of thin-film transistors formed through the same process as the driving circuits of the pixels PX, for example, a low temperature polycrystalline silicon (LTPS) process, or a low temperature polycrystalline oxide (LTPO) process.

In an embodiment, the signal lines SGL includes scan lines SL, data lines DL, a power line PL, and a control signal line CSL. The scan lines SL may be respectively connected to corresponding pixels PX among the pixels PX, and the data lines DL may be respectively connected to corresponding pixels PX among the pixels PX. The power line PL is connected to the pixels PX. The control signal line CSL may supply control signals to the scan driving circuit SDC.

In an embodiment, the signal lines SGL overlap the display region DP-DA and the non-display region DP-NDA and may include a pad portion and a line portion. The line portion overlaps the display region DP-DA and the non-display region DP-NDA. The pad portion is connected to an end of the line portion and is disposed in the non-display region DP-NDA, and overlaps a corresponding signal pad among the signal pads PD. A region, of the non-display region DP-NDA, in which the signal pads PD are disposed may be defined as a pad region NDA-PD.

In an embodiment, the line portion connected to the pixel PX substantially constitutes most of the signal lines SGL and is connected to transistors (not shown) of the pixel PX. The line portion may have a single-layered/multi-layered structure, and may be a single body, or may include at least two sub-portions. The at least two sub-portions are respectively disposed on different layers, and may be connected through a contact hole penetrating an insulating layer disposed between the at least two sub-portions.

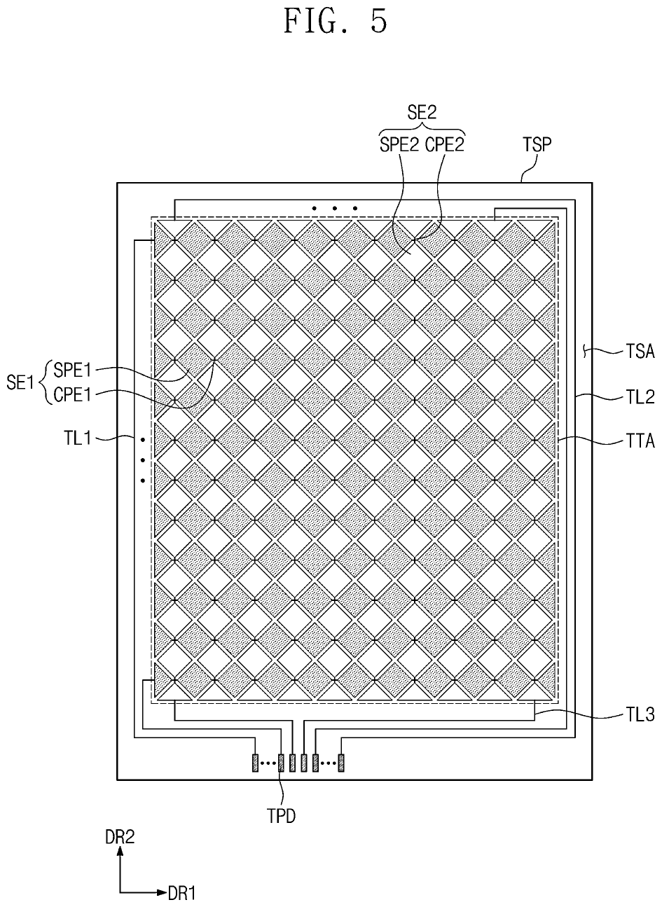

FIG. 5 is a plan view of the touch sensing panel illustrated in FIGS. 2A and 2B, according to an embodiment.

In an embodiment and referring to FIG. 5, a touch sensing panel TSP may obtain information such as a location or a strength of an external touch input by sensing the user's touch input TC (see FIG. 1). The touch sensing panel TSP may include a touch region TTA and a touch peripheral region TSA which are disposed on a plane. In an embodiment, the touch peripheral region TSA may be defined along an edge portion of the touch region TTA. The touch region TTA and the touch peripheral region TSA of the touch sensing panel TSP may respectively correspond to the display region DA and the non-display region NDA of the display device DD illustrated in FIG. 1.

In an embodiment, the touch sensing panel TSP includes a plurality of first sensing electrodes SE1, a plurality of second sensing electrodes SE2, a plurality of sensing lines TL1, TL2, and TL3, and a plurality of sensing pads TPD.

In an embodiment, the first sensing electrodes SE1 and the second sensing electrodes SE2 are disposed in the touch region TTA. The touch sensing panel TSP may obtain information about a touch input through a capacitance change between the first sensing electrodes SE1 and the second sensing electrodes SE2.

In an embodiment, each of the first sensing electrodes SE1 may extend along the first direction DR1 and may be arranged along the second direction DR2. The first sensing electrodes SE1 may each include a plurality of first sensing patterns SPE1 and a plurality of first connection patterns CPE1.

The first sensing patterns SPE1 that constitute one first sensing electrode may be arranged to be spaced apart from each other along the first direction DR1. In an embodiment, the first sensing patterns SPE1 are illustrated shaded with respect to the first sensing patterns SPE1 for easy description. The first connection patterns CPE1 may be disposed between the first sensing patterns SPE1 to connect two adjacent first sensing patterns SPE1.

In an embodiment, each of the second sensing electrodes SE2 may extend along the second direction DR2 and may be arranged along the first direction DR1. The second sensing electrodes SE2 may each include a plurality of second sensing patterns SPE2 and a plurality of second connection patterns CPE2.

The second sensing patterns SPE2 that constitute one second sensing electrode are arranged to be spaced apart from each other along the second direction DR2. The second connection patterns CPE2 are disposed between the second sensing patterns SPE2 to connect two adjacent second sensing patterns SPE2.

In an embodiment, the sensing lines TL1, TL2, and TL3 are disposed in the touch peripheral region TSA, where the sensing lines TL1, TL2, and TL3 may include first sensing lines TL1, second sensing lines TL2, and third sensing lines TL3. The first sensing lines TL1 may be connected to the first sensing electrodes SE1 and the second sensing lines TL2 may be connected to one ends of the second sensing electrodes SE2.

The third sensing lines TL3 may be connected to other ends of the second sensing electrodes SE2. The other ends of the second sensing electrodes SE2 may be portions opposed to the one ends of the second sensing electrodes SE2. According to an embodiment, the second sensing electrodes SE2 may be connected to the second sensing lines TL2 and the third sensing lines TL3. Accordingly, the second sensing electrodes SE2 having a relatively greater length than the first sensing electrodes SE1 may maintain a uniform sensitivity according to a region. This is illustrated as an example in an embodiment, and the third sensing lines TL3 may be omitted, and the invention is not limited to any one embodiment.

In an embodiment, the sensing pads TPD are disposed in the touch peripheral region TSA, where the sensing pads TPD may be respectively connected to the sensing lines TL1, TL2, and TL3 to electrically connect an external signal to each of the first sensing electrodes SE1 and the second sensing electrodes SE2. The sensing pads TPD may be connected to the second circuit board FCB2 (see FIG. 2B).

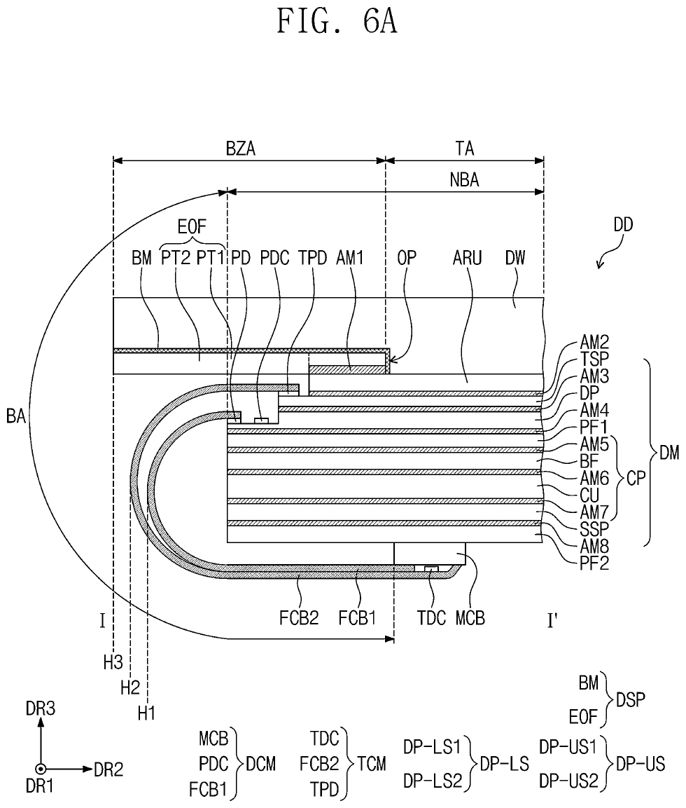

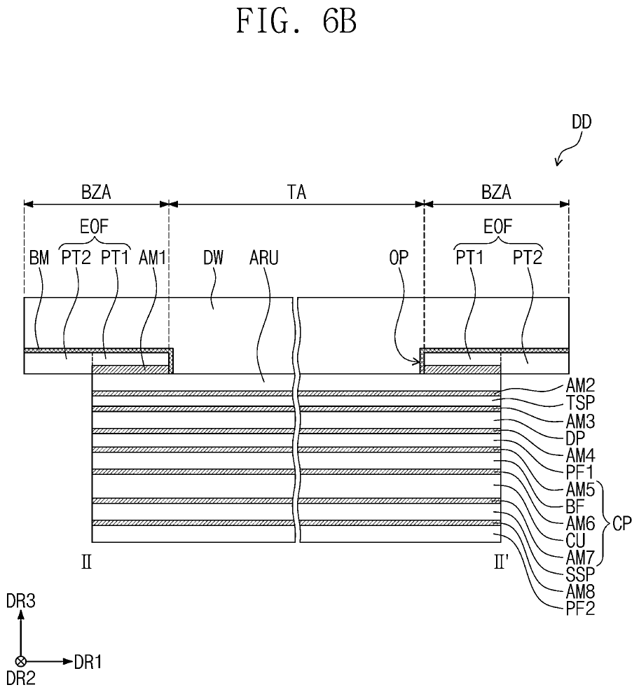

FIG. 6A is a cross-sectional view of a display device corresponding to line I-I′ illustrated in FIG. 2B, according to an embodiment. FIG. 6B is a cross-sectional view of the display device corresponding to line II-II′ illustrated in FIG. 2B, according to an embodiment.

A first circuit board FCB1 and a second circuit board FCB2 in FIG. 6A are illustrated in a bent state as one example of an embodiment.

In an embodiment, a display panel DP is expressed as a single layer in FIGS. 6A and 6B, but the display panel DP may have a multi-layered structure. The display panel DP may include a base layer, a circuit layer, a light-emitting element layer, and an encapsulation layer. In addition, those skilled in the art related to the invention may understand that the display panel DP may further include other general-purpose components.

Description of the same components as those already described with reference to the drawings described above, among the components illustrated in FIGS. 6A and 6B will be omitted or will be briefly made.

In an embodiment and referring to FIGS. 6A and 6B, a display device DD may include a display module DM, a window support layer DSP disposed on the display module DM, and a coated window DW directly disposed on the window support layer DSP. The display device DD may include a display panel DP, an anti-reflective layer ARU, a support film EOF, a light-shielding pattern BM, a first protective layer PF1, a second protective layer PF2, a protective panel CP, a support panel SSP, a touch sensing panel TSP, the coated window DW, and first to eighth adhesive layers AM1 to AM8, respectively. The display device DD may include a non-bent region NBA, and a bent region BA in which the first and second circuit boards FCB1 and FCB2, respectively, are bent.

In an embodiment, the first adhesive layer AMI to the eighth adhesive layer AM8 to be described below may be a pressure sensitive adhesive (PSA) film, an optically clear adhesive (OCA) film, or an optically clear adhesive resin (OCR). The first adhesive layer AM1 to the eighth adhesive layer AM8 may include a light-curing adhesive material or a heat-curing adhesive material, and the material is not specially limited. The first adhesive layer AMI to the eighth adhesive layer AM8 may be partially omitted.

In an embodiment, the display panel DP may be disposed between the touch sensing panel TSP and the protective panel CP and may display an image in response to an electrical signal.

In an embodiment, a driving control module DCM may be coupled to an end of the display panel DP. The driving control module DCM may include the first circuit board FCB1, the panel driving circuit PDC, and the main circuit board MCB. The first circuit board FCB1 may electrically connect the main circuit board MCB and the display panel DP. The panel driving circuit PDC may be disposed on the display panel DP.

The first circuit board FCB1 may be electrically connected to the signal pads PD. In this embodiment, the signal pads PD may correspond to the signal pads PD (see FIG. 4) disposed in the pad region NDA-PD (see FIG. 3) in FIG. 4. The first circuit board FCB1 may be bent, where one end of the first circuit board FCB1 may be disposed on a front surface of the display panel DP, and the other end of the first circuit board FCB1 may be disposed on a rear surface of the display panel DP. The other end of the first circuit board FCB1 may be connected to the main circuit board MCB.

In an embodiment, the touch sensing panel TSP may be disposed on the display panel DP, and may sense an input signal. In another embodiment, a third adhesive layer AM3 that adheres the touch sensing panel TSP and the display panel DP may be omitted. The touch sensing panel TSP may be disposed between the display panel DP and the anti-reflective layer ARU, and may be electrically connected to the second circuit board FCB2.

In an embodiment, the touch control unit TCM may include the touch driving circuit TDC, the second circuit board FCB2, and the sensing pads TPD. The touch control unit TCM may be coupled to an end of the touch sensing panel TSP. The sensing pads TPD may be disposed on the touch sensing panel TSP. In this embodiments, the sensing pads TPD may be the same as the sensing pads TPD (see FIG. 5) illustrated in FIG. 5.

In an embodiment, the second circuit board FCB2 may be connected to an end portion of the touch sensing panel TSP to electrically connect the main circuit board MCB and the touch sensing panel TSP. The second circuit board FCB2 may transmit an input signal sensed by the touch sensing panel TSP. The second circuit board FCB2 may be bent with the first circuit board FCB1. One end of the second circuit board FCB2 may be disposed on the front surface of the touch sensing panel TSP, and the other end of the second circuit board FCB2 may be disposed on the rear surface of the touch sensing panel TSP, where the other end of the second circuit board FCB2 may be connected to the main circuit board MCB.

In an embodiment, the anti-reflective layer ARU may be disposed on the upper surface of the display panel DP and may be disposed on the touch sensing panel TSP. The anti-reflective layer ARU may be disposed between the display panel DP and the coated window DW and may overlap the non-bent region NBA. According to an embodiment, the anti-reflective layer ARU may not overlap the bent region BA. The anti-reflective layer ARU may be adhered onto the touch sensing panel TSP by the second adhesive layer AM2. However, in another embodiment, the second adhesive layer AM2 may be omitted according to need.

In an embodiment, the window support layer DSP may be disposed on the upper surface of the anti-reflective layer ARU. The window support layer DSP may overlap an edge portion of the anti-reflective layer ARU. The window support layer DSP may overlap the bezel region BZA. The window support layer DSP may not overlap the transmission region TA.

The window support layer DSP may include the support film EOF and the light-shielding pattern BM. The support film EOF may overlap the bezel region BZA and may not overlap the transmission region TA.

In an embodiment, the support film EOF may be disposed on the display module DM. The support film EOF may be disposed on the upper surface of the anti-reflective layer ARU. The support film EOF may be disposed on an edge portion of the anti-reflective layer ARU, where one portion of the support film EOF may overlap the anti-reflective layer ARU and the other portion of the support film EOF may not overlap the anti-reflective layer ARU.

The one portion of the support film EOF overlapping the anti-reflective layer ARU may be defined as a first portion PT1, and the other portion of the support film EOF not overlapping the anti-reflective layer ARU may be defined as a second portion PT2. The second portion PT2 may be disposed outside of the first portion PT1. Although not shown, when viewed on a plane, the second portion PT2 may surround the first portion PT1.

In an embodiment, the edge portion of the support film EOF may be disposed outside of the edge portion of the anti-reflective layer ARU. The edge portion of the second portion PT2 may be disposed outside of the edge portion of the anti-reflective layer ARU. An outer side surface of the second portion PT2 may protrude from an outer side surface of the anti-reflective layer ARU in a direction extending away from the transmission region TA. The outer side surface of the second portion PT2 may be defined as a side surface opposed to an inner side surface facing the opening OP. As illustrated in FIG. 6A, since the second portion PT2 protrudes from an outer side surface of the anti-reflective layer ARU, the second portion PT2 may cover bent portions of the first circuit board FCB1 and the second circuit board FCB2 on a plane.

In an embodiment, the support film EOF may serve as a base capable of applying a resin material for forming the coated window DW. The support film EOF may be disposed under the coated window DW so that the resin material, which is in a liquid state, may be applied on the support film EOF. In addition, since the second portion PT2 of the support film EOF covers the first circuit board FCB1 and the second circuit board FCB2 which is bent on a plane, when the resin material is applied, the resin material may be prevented from flowing into the first circuit board FCB1 and the second circuit board FCB2 to be cured. When the resin material flows into the first circuit board FCB1 and the second circuit board FCB2 and is cured, a crack may be generated in bending the first circuit board FCB1 and the second circuit board FCB2. The support film EOF may prevent such a crack risk.

In an embodiment, the lower surface of the support film EOF may have a step. Moreover, the first portion PT1 may have a smaller thickness than the second portion PT2 and the first portion PT1 may have a higher lower surface than the second portion PT2.

In an embodiment, the first adhesive layer AM1 may be disposed on the edge portion of the anti-reflective layer ARU and may overlap the bezel region BZA and may not overlap the transmission region TA.

The first adhesive layer AM1 may be disposed between the first portion PT1 and the anti-reflective layer ARU. The first adhesive layer AM1 may be disposed between the lower surface of the first portion PT1 and the upper surface of the anti-reflective layer ARU. The support film EOF may be attached to the edge portion of the anti-reflective layer ARU by the first adhesive layer AM1.

As an example, the lower surface of the first adhesive layer AM1 and the lower surface of the second portion PT2 may be disposed on the same plane. In this embodiment, a thickness of the second portion PT2 may be the same as a sum of a thickness of the first portion PT1 and a thickness of the first adhesive layer AM1.

In an embodiment, when the support film EOF overlaps the entire upper surface of the anti-reflective layer ARU, usage of the used support film EOF may increase. In addition, usage of the first adhesive layer AM1 to adhere the support film EOF and the anti-reflective layer ARU may increase.

The support film EOF and the first adhesive layer AM1, according to an embodiment, may each have a frame shape, and may be disposed on the edge portion of the anti-reflective layer ARU overlapping the bezel region BZA to cover the edge portion of the display module DM and the first and second circuit boards FCB1 and FCB2, respectively, on a plane. The support film EOF and the first adhesive layer AM1 may not be disposed on the upper surface of the anti-reflective layer ARU overlapping the transmission region TA. Accordingly, usage of the support film EOF and usage of the first adhesive layer AM1 may be reduced. Thus, a manufacturing cost of the display device DD may be reduced.

In an embodiment, the light-shielding pattern BM may be disposed on the upper surface of the support film EOF. The light-shielding pattern BM may be disposed on the upper surface of the first portion PT1 and the upper surface of the second portion PT2. Since the support film EOF may extend outward from the bent portions of the first and second circuit boards FCB1 and FCB2, the light-shielding pattern BM disposed on the support film EOF may also extend outward from the bent portions of the first and second circuit boards FCB1 and FCB2. Accordingly, the first and second flexible circuit boards FCB1 and FCB2 disposed under the light-shielding pattern BM may not be viewed from the outside.

In an embodiment, the light-shielding pattern BM may be disposed on an inner side surface of the support film EOF defining the opening OP. The light-shielding pattern BM may be disposed on an inner side surface of the first portion PT1 defining the opening OP. The light-shielding pattern BM may be disposed on an inner side surface of the first adhesive layer AMI facing the opening OP. Since the light-shielding pattern BM covers the inner side surface of the first portion PT1 and the inner side surface of the first adhesive layer AM1, when the transmission region TA is viewed at an angle of about 0° to about 90°, the light-shielding pattern BM may prevent an edge portion of the first adhesive layer AM1 and the support film EOF from being viewed.

In an embodiment, the coated window DW may be disposed on the window support layer DSP and the anti-reflective layer ARU. The coated window DW may cover the upper surface and the inner side surface of the window support layer DSP. The coated window DW may be disposed on the upper surface of the anti-reflective layer ARU through the opening OP.

In an embodiment, the transmission region TA of the coated window DW may be disposed on the upper surface of the anti-reflective layer ARU, and the bezel region BZA of the coated window DW may be disposed on the upper surface of the light-shielding pattern BM. The lower surface of the coated window DW may have a shape corresponding to the upper surface of the window support layer DSP and the upper surface of the anti-reflective layer ARU. The lower surface of the transmission region TA may be lower than the lower surface of the bezel region BZA. The transmission region TA may have a greater thickness than the bezel region BZA.

In an embodiment, the edge portion of the coated window DW may be disposed more outside than the edge portion of the display module DM. The outer side surface of the coated window DW may protrude toward the bent region BA from the outer side surface of the anti-reflective layer ARU. The outer side surface of the coated window DW may be aligned with the outer side surface of the second portion PT2 in the third direction DR3. The bezel region BZA of the coated window DW may cover the first circuit board FCB1 and the second circuit board FCB2 on a plane.

In an embodiment, the first protective layer PF1 may be disposed on the lower surface of the display panel DP to protect the display panel DP from an impact. The first protective layer PF1 may be adhered to the lower surface of the display panel DP by a fourth adhesive layer AM4. However, in another embodiment, the fourth adhesive layer AM4 may be omitted according to need.

In an embodiment, the second protective layer PF2 may be coupled to the driving control module DCM. The second protective layer PF2 may be disposed on the lower surface of the display panel DP. The second protective layer PF2 may be adhered to the support panel SSP by an eighth adhesive layer AM8. However, in this embodiment, the eighth adhesive layer AM8 may be omitted according to need.

In an embodiment, the protective panel CP may be disposed under the display panel DP and may protect the display panel DP from an impact transmitted from the lower portion thereof.

In an embodiment, the protective panel CP may include a fifth adhesive layer AM5, a barrier layer BF, a sixth adhesive layer AM6, a cushion layer CU, and a seventh adhesive layer AM7. The barrier layer BF may be adhered to the lower surface of the first protective layer PF1 by the fifth adhesive layer AM5. The barrier layer BF may have a color having a low light-transmittance to prevent components under the barrier layer BF from being viewed.

The barrier layer BF may include a flexible synthetic resin film. For example, the barrier layer BF may be a film including polyimide (PI), polyethyleneterephthalate (PET), or the like. However, a material of the barrier layer BF is not limited thereto, and the barrier layer BF may have various material according to need.

The cushion layer CU may be adhered to the lower surface of the barrier layer BF by the sixth adhesive layer AM6. The cushion layer CU may absorb an impact transmitted from the lower portion of the display panel DP. The cushion layer CU may be a material, having a great elasticity, such as a foam sheet in which a multiple openings are formed.

In an embodiment, the support panel SSP may be disposed under the protective panel CP to support the display panel DP and the protective panel CP and may be a metal plate having a rigidity of at least a predetermined standard. For example, in an embodiment, the support panel SSP may be a stainless-steel plate. The support panel SSP may have a black color so as to shield external light incident on the display panel DP.

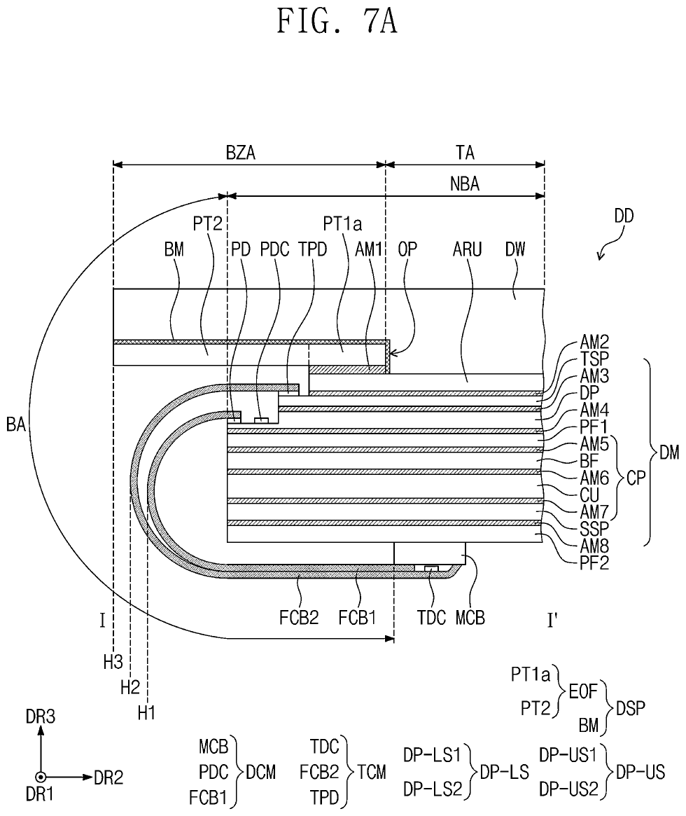

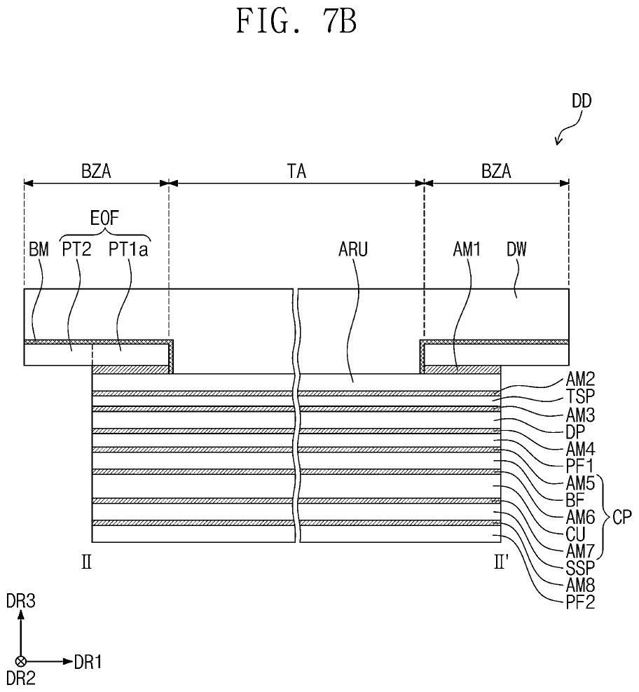

FIG. 7A is a cross-sectional view corresponding to line I-I′ illustrated in FIG. 2B, according to an embodiment, and FIG. 7B is a cross-sectional view corresponding to line II-II′ illustrated in FIG. 2B, according to an embodiment.

A display device DD illustrated in FIGS. 7A and 7B will be described focusing on a difference from the display device DD illustrated in FIGS. 6A and 6B.

In an embodiment and referring to FIGS. 7A and 7B, a support film EOF may include a first portion PT1a and a second portion PT2. The first portion PT1a may have the same thickness as the second portion PT2. The lower surface of the first portion PT1a and the lower surface of the second portion PT2 may be disposed on the same plane.

In an embodiment, a first adhesive layer AM1 may be disposed between the first portion PT1a and an anti-reflective layer ARU. The support film EOF and the anti-reflective layer ARU may be attached to each other by the first adhesive layer AM1.

The first adhesive layer AM1 may be disposed on the lower surface of the first portion PT1a. The lower surface of the first adhesive layer AM1 may be disposed lower than the lower surface of the second portion PT2. The first adhesive layer AM1 may be disposed on the upper surface of the anti-reflective layer ARU. The first adhesive layer AM1 may be disposed on the edge portion of the anti-reflective layer ARU, where the first adhesive layer AM1 may overlap a bezel region BZA, and may not overlap a transmission region TA.

Since the first adhesive layer AM1 and the support film EOF are disposed on the edge portion and not the entire upper surface of the anti-reflective layer ARU, usage of the first adhesive layer AM1 and usage of the support film EOF may be reduced. Accordingly, a manufacturing cost of the display device DD may be reduced.

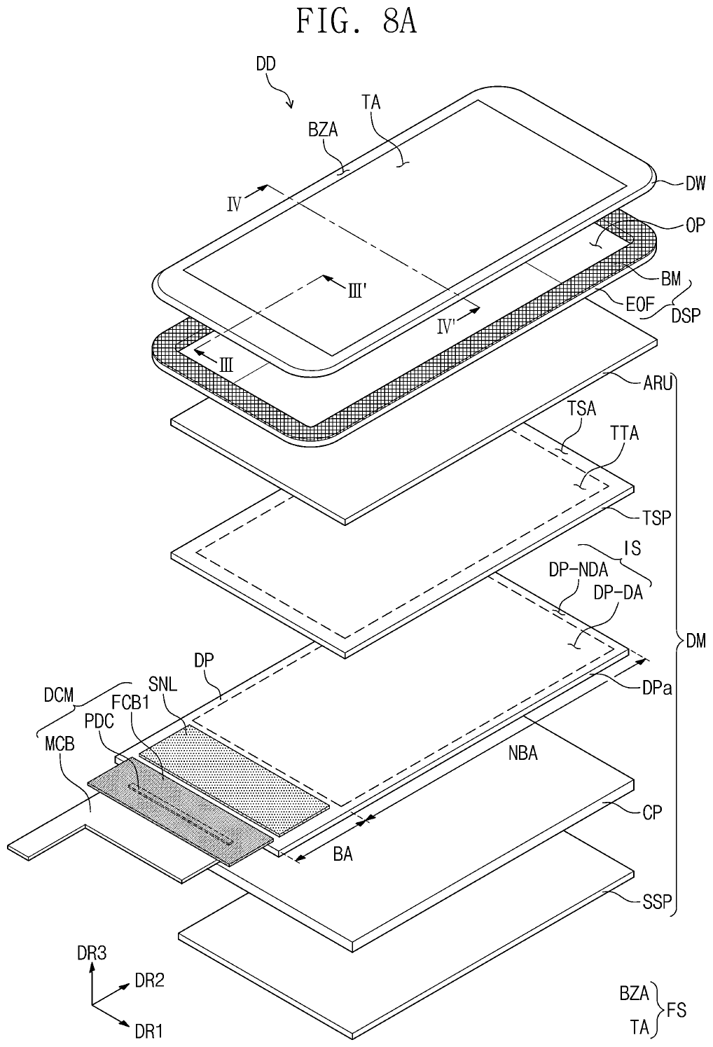

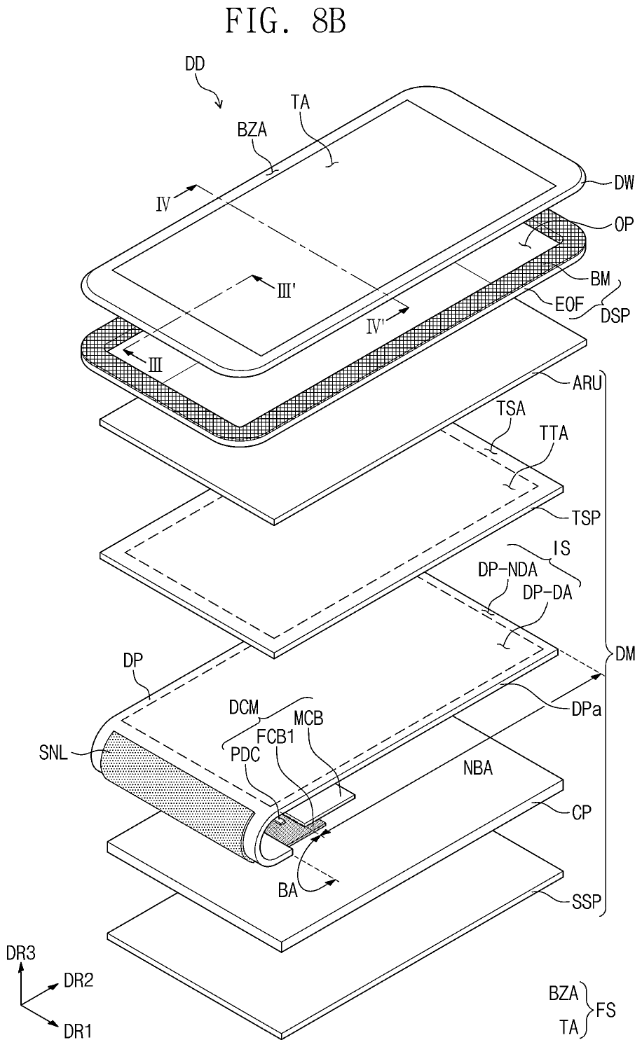

FIG. 8A is an exploded perspective view of a display device DD in a state in which a bent region BA is not bent, according to an embodiment, and FIG. 8B is an exploded perspective view of the display device DD in a state in which the bent region BA is bent, according to an embodiment.

Description of the same components as those already described with reference to the drawings described above, among the components illustrated in FIGS. 8A and 8B will be omitted or will be briefly made.

In an embodiment and referring to FIGS. 8A and 8B, the display device DD may include a coated window DW, a window support layer DSP, and a display module DM. A display panel DPa may be disposed between the coated window DW and the support panel SSP, where the display panel DPa may display an image in response to an electrical signal.

In an embodiment, the display panel DPa may include a non-bent region NBA and a bent region BA extending from and bent from an end of the non-bent region NBA. The bent region BA may extend from the non-bent region NBA in an opposite direction of the second direction DR2, where the bent region BA may be bent to face the rear surface of the non-bent region NBA.

In an embodiment, the image IM (see FIG. 1) provided by the display device DD may be displayed on the front surface IS of the display panel DPa. The front surface IS of the display panel DPa may include a display region DP-DA and a non-display region DP-NDA. In this case, the display region DP-DA may correspond to the display region DA in FIG. 1, and the non-display region DP-NDA may correspond to the non-display region NDA in FIG. 1.

In an embodiment, a bending protection layer SNL may be disposed on the display panel DPa, and may be bent with the bent region BA together. The bending protection layer SNL may prevent a bent portion of the display panel DPa from being damaged by an external impact, or by external foreign matters being introduced thereto. The bending protection layer SNL illustrated in the drawing is only exemplarily expressed, and a shape of the bending protection layer SNL may be changed according to need.

In an embodiment, the bending protection layer SNL may be disposed on the front surface of the display panel DPa to protect the bent portion of the display panel DPa. The bending protection layer SNL may include a plastic film as a base layer. The bending protection layer SNL may include the plastic film including any one selected from the group consisting of polyethersulphone (PES), polyacrylate (PAR), polyetherimide (PEI), polyethylenenaphthalate (PEN), polyethyleneterephthalate (PET), polyphenylenesulfide (PPS), polyallylate, polyimide (PI), polycarbonate (PC), polyaryleneethersulfone, and a combination thereof.

In an embodiment, a material that constitutes the bending protection layer SNL is not limited to the plastic resins, and may include an organic/inorganic composite material. The bending protection layer SNL may include a porous organic layer, and an inorganic material filling pores of the organic layer. The bending protection layer SNL may include a single-layered or multi-layered structure.

In an embodiment, the driving control module DCM includes a main circuit board MCB (or driving circuit board), a first circuit board FCB1, and a panel driving circuit PDC. The first circuit board FCB1 may be connected to an end portion of the display panel DPa to electrically connect the main circuit board MCB and the display panel DPa.

In an embodiment, the first circuit board FCB1 may electrically connect the main circuit board MCB and the display panel DPa, and the panel driving circuit PDC may be mounted on the first circuit board FCB1. This may be a method for mounting the panel driving circuit PDC as a chip-on-film method. The panel driving circuit PDC may be realized as an integrated circuit. Although not shown separately, a plurality of active elements and passive elements may be mounted on the main circuit board MCB. The main circuit board MCB may be a rigid circuit board or a flexible circuit board, and the first circuit board FCB1 may be a flexible circuit board. The main circuit board MCB may be placed on the rear surface of the display panel DPa.

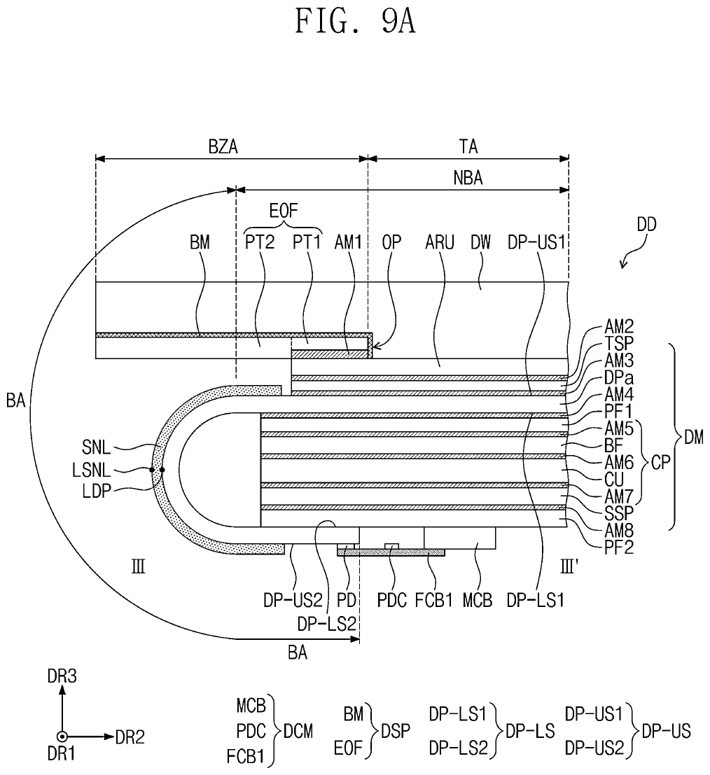

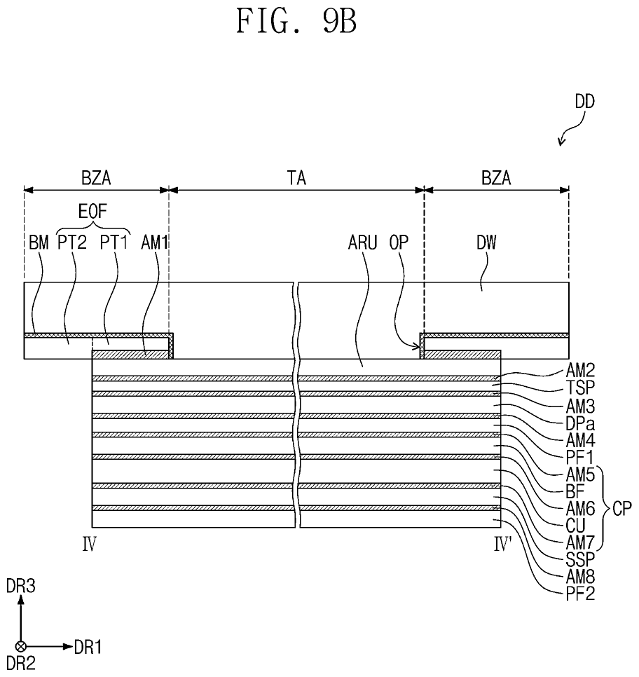

FIG. 9A is a cross-sectional view of a display device corresponding to line III-III′ illustrated in FIG. 8B, according to an embodiment. FIG. 9B is a cross-sectional view of the display device corresponding to line IV-IV′ illustrated in FIG. 8B, according to an embodiment.

Description of the same components as those already described with reference to the drawings described above, among the components illustrated in FIGS. 9A and 9B will be omitted or will be briefly made.

In an embodiment, the display device DD may include a display module DM, a support film EOF, and a coated window DW disposed on the display module DM. The display module DM may include a display panel DPa, an anti-reflective layer ARU, a first protective layer PF1, a second protective layer PF2, a protective panel CP, a support panel SSP, and first to eighth adhesive layers AM1 to AM8, respectively. The adhesive layers AM1 to AM8 may be partially omitted.

In an embodiment, an end of the bent region BA of the display panel DPa may be bent to be disposed on the lower surface of the second protective layer PF2. The end of the bent region BA may face the non-bent region NBA in the third direction DR3. A first upper surface DP-US1 of the display panel DPa may be disposed to be more adjacent to the coated window DW than a first lower surface DP-LS1. A second upper surface DP-US2 of the display panel DPa may be spaced apart from the coated window DW farther than a second lower surface DP-LS2.

In an embodiment, the bending protection layer SNL may be disposed on the upper surface DP-US of the display panel DPa to be bent with the bent region BA together. The bending protection layer SNL may overlap the bent region BA. The bending protection layer SNL may partially overlap the non-bent region NBA of the display panel DPa.

In an embodiment, a driving control module DCM may be coupled to an end of the display panel DPa, where the driving control module DCM may include a first circuit board FCB1, a panel driving circuit PDC, and a main circuit board MCB. The first circuit board FCB1 may electrically connect the main circuit board MCB and the display panel DPa, and the panel driving circuit PDC may be mounted on the first circuit board FCB1. In an embodiment, a state in which the panel driving circuit PDC is mounted on the first circuit board FCB1 is illustrated, but a position of the panel driving circuit PDC is not limited thereto. For example, in another embodiment, the panel driving circuit PDC may be directly disposed on the upper surface DP-US of the display panel DPa.

In an embodiment, the first circuit board FCB1 may be electrically connected to signal pads PD. In this case, the signal pads PD may correspond to the signal pads PD disposed in the pad region NDA-PD in FIG. 4. The first protective layer PF1 may be disposed on the first lower surface DP-LS1 of the display panel DPa to protect the display panel DPa from an impact. The first protective layer PF1 may be adhered to the first lower surface DP-LS1 by a third adhesive layer AM3. However, in another embodiment, the third adhesive layer AM3 may be omitted according to need.

In an embodiment, the support film EOF may be disposed on the anti-reflective layer ARU and may overlap the edge portion of the anti-reflective layer ARU.

The support film EOF may extend to overlap the bent region BA and the non-bent region NBA. The support film EOF may cover the display module DM disposed under the support film EOF on a plane. The support film EOF may cover the bent region BA and the bending protection layer SNL of the display panel DP on a plane.

Since the support film EOF covers the bent region BA and a bent portion of the bending protection layer SNL, when a resin material is applied, the resin material may be prevented from flowing into the bent region BA and the bending protection layer SNL and being cured. When the resin material flows into the bent region BA and the bending protection layer SNL to be cured, a crack may be generated in bending the bent region BA and the bending protection layer SNL of the display panel DPa. The support film EOF may prevent such a crack risk.

In an embodiment, the support film EOF may include a first portion PT1 and a second portion PT2. The first portion PT1 may overlap the non-bent region NBA. The first portion PT1 may overlap the bezel region BZA. The first portion PT1 may overlap the anti-reflective layer ARU. The first portion PT1 may be disposed adjacent to the edge portion of the anti-reflective layer ARU.

The second portion PT2 may extend from the first portion PT1 in the second direction DR2. The second portion PT2 may be disposed outside of the first portion PT1. The second portion PT2 may be disposed outside of the display module DM in a direction getting farther from the transmission region TA. On a plane, the second portion PT2 may cover the bent region BA of the display module DM.

In an embodiment, the first portion PT1 may have a smaller thickness than the second portion PT2. The lower surface of the first portion PT1 may be disposed higher than the lower surface of the second portion PT2. That is, there may be a step on the lower surface of the support film EOF.

In an embodiment, the first adhesive layer AM1 may be disposed between the first portion PT1 and the anti-reflective layer ARU. The first adhesive layer AM1 may be disposed on the edge portion of the anti-reflective layer ARU. The first adhesive layer AM1 may be disposed between the lower surface of the first portion PT1 and the upper surface of the anti-reflective layer ARU. The support film EOF may be attached to the edge portion of the anti-reflective layer ARU by the first adhesive layer AM1.

In an embodiment, the lower surface of the first adhesive layer AM1 and the lower surface of the second portion PT2 may be disposed on the same plane. In this case, a thickness of the second portion PT2 may be the same as a sum of a thickness of the first portion PT1 and a thickness of the first adhesive layer AM1.

In an embodiment, the support film EOF may not overlap the transmission region TA. Accordingly, usage of the support film EOF may be reduced, and usage of the first adhesive layer AMI that adheres the support film EOF on the upper surface of the anti-reflective layer ARU may be reduced. Accordingly, a manufacturing coast of the display device DD may be reduced.

In an embodiment, the light-shielding pattern BM may be disposed on the upper surface of the support film EOF. The light-shielding pattern BM may be disposed on the upper surface of the first portion PT1 and the upper surface of the second portion PT2. Since the support film EOF extends outward from the bent region BA, the light-shielding pattern BM disposed on the support film EOF may also extend outward from the bent region BA. Accordingly, the bent region BA disposed under the light-shielding pattern BM may not be viewed from the outside.

The light-shielding pattern BM may be disposed on an inner side surface of the support film EOF defining the opening OP. The light-shielding pattern BM may be disposed on an inner side surface of the first portion PT1 defining the opening OP. The light-shielding pattern BM may be disposed on an inner side surface of the first adhesive layer AM1 facing the opening OP. Since the light-shielding pattern BM covers the inner side surface of the first portion PT1 and the inner side surface of the first adhesive layer AM1, when the transmission region TA is viewed at an angle of about 0° to about 90°, the light-shielding pattern BM may prevent the edge portion of the first adhesive layer AM1 and the support film EOF from being viewed.

In an embodiment, the coated window DW may be disposed on the window support layer DSP and the anti-reflective layer ARU. The coated window DW may cover the upper surface and the inner side surface of the window support layer DSP. The coated window DW may be disposed on the upper surface of the anti-reflective layer ARU through the opening OP.

In an embodiment, the transmission region TA of the coated window DW may be disposed on the upper surface of the anti-reflective layer ARU, and the bezel region BZA of the coated window DW may be disposed on the upper surface of the light-shielding pattern BM. The lower surface of the coated window DW may have a shape corresponding to the upper surface of the window support layer DSP and the upper surface of the anti-reflective layer ARU. The lower surface of the transmission region TA may be lower than the lower surface of the bezel region BZA. Additionally, the transmission region TA may have a greater thickness than the bezel region BZA.

In an embodiment, the edge portion of the coated window DW may be disposed outside of the edge portion of the display module DM. An outer side surface of the coated window DW may protrude toward the bent region BA from an outer side surface of the anti-reflective layer ARU. The outer side surface of the coated window DW may be aligned with an outer side surface of the second portion PT2 in the third direction DR3. The bezel region BZA of the coated window DW may cover the bent region BA on a plane.

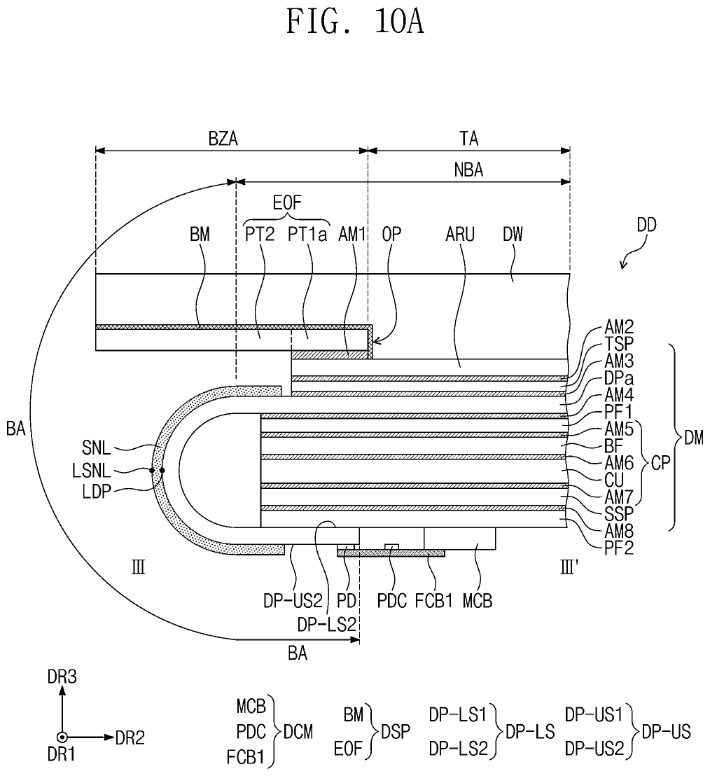

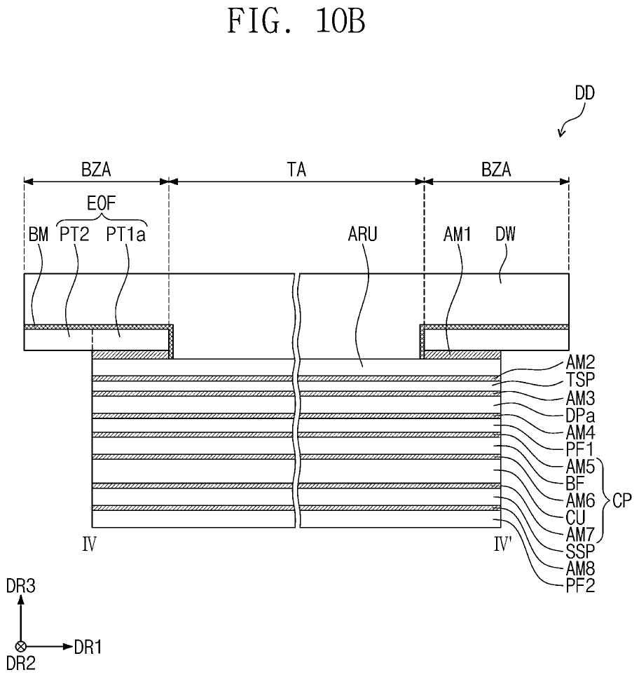

FIGS. 10A and 10B are diagrams for describing a display device including a window support layer, according to an embodiment.

FIG. 10A is a cross-sectional view of a display device DD corresponding to line III-III′ illustrated in FIG. 8B, according to an embodiment, and FIG. 10B is a cross-sectional view of the display device DD corresponding to line IV-IV′ illustrated in FIG. 8B, according to an embodiment.

In an embodiment, the display device DD illustrated in FIGS. 10A and 10B will be briefly described focusing on a difference from the display device DD illustrated in FIGS. 9A and 9B.

In an embodiment and referring to FIGS. 10A and 10B, the support film EOF may include a first portion PT1a and a second portion PT2. The first portion PT1a may have the same thickness as the second portion PT2. A lower surface of the first portion PT1a and a lower surface of the second portion PT2 may be disposed on the same plane.

In an embodiment, the first adhesive layer AM1 may be disposed between the first portion PT1a and the anti-reflective layer ARU. The support film EOF and the anti-reflective layer ARU may be attached to each other by the first adhesive layer AM1.

The first adhesive layer AM1 may be disposed on the lower surface of the first portion PT1a and the lower surface of the first adhesive layer AM1 may be lower than the lower surface of the second portion PT2. The first adhesive layer AM1 may be disposed on the upper surface of the anti-reflective layer ARU and the first adhesive layer AM1 may be disposed on the edge portion of the anti-reflective layer ARU. The first adhesive layer AM1 may overlap the bezel region BZA, and may not overlap the transmission region TA.

In an embodiment, since the first adhesive layer AM1 and the support film EOF are disposed on the edge portion of the anti-reflective layer ARU, and not the entire upper surface thereof, usage of the first adhesive layer AM1 and usage of the support film EOF may be reduced. Accordingly, a manufacturing cost of the display device DD may be reduced.

According to an embodiment, a support film may have a frame shape, and may be attached onto an edge portion of an anti-reflective layer by an adhesive layer. Accordingly, compared to a state in which the support film is disposed on the entire upper surface of the anti-reflective layer, usage of the adhesive layer and usage of the support film may be reduced, thereby simplifying a process of manufacturing a display device, and reducing a cost to improve processability.

In the above, description has been made with reference to embodiments of the invention, but those skilled in the art or those of ordinary skill in the relevant technical field may understand that various modifications and changes may be made to the invention within the scope of the invention. In addition, the embodiments are not intended to limit the invention. Therefore, the scope of the invention should not be limited to any single embodiment described herein or otherwise. Moreover, embodiments or parts of the embodiments may be combined in whole or in part without departing from the scope of the invention.

What is claimed is:

1. A display device comprising:
a display panel;
an anti-reflective layer disposed on the display panel;
a support film having a frame shape when viewed on a plane, and disposed on an edge portion of the anti-reflective layer; and
a coated window disposed on an upper surface of the support film and an upper surface of the anti-reflective layer.

2. The display device of claim 1, wherein an edge portion of the support film is disposed outside of the edge portion of the anti-reflective layer.

3. The display device of claim 2, wherein the support film comprises:
a first portion overlapping the anti-reflective layer; and
a second portion extending from the first portion and surrounding the first portion when viewed on the plane, and
an edge portion of the second portion, wherein the edge portion of the second portion is disposed outside of the edge portion of the anti-reflective layer.

4. The display device of claim 3, wherein the first portion has a smaller thickness than the second portion.

5. The display device of claim 4, wherein a lower surface of the first portion is higher than a lower surface of the second portion.

6. The display device of claim 4, further comprising an adhesive layer disposed between the first portion and the anti-reflective layer,
wherein a sum of a thickness of the first portion and a thickness of the adhesive layer is the same as a thickness of the second portion.

7. The display device of claim 6, further comprising a light-shielding pattern covering an upper surface of the support film, an inner side surface of the support film defining an opening, and an inner side surface of the adhesive layer disposed on a same plane as the inner side surface of the support film.

8. The display device of claim 3, wherein the first portion has the same thickness as the second portion.

9. The display device of claim 8, further comprising an adhesive layer disposed between the first portion and the anti-reflective layer.

10. The display device of claim 9, further comprising a light-shielding pattern covering an upper surface of the support film, an inner side surface of the support film defining an opening, and an inner side surface of the adhesive layer disposed on a same plane as the inner side surface of the support film.

11. The display device of claim 2, further comprising a circuit board bent so that one end thereof is disposed on a front surface of the display panel, and an other end thereof is disposed on a rear surface of the display panel,
wherein when viewed on the plane, the support film covers a bent portion of the circuit board.

12. The display device of claim 2, wherein the display panel comprises a non-bent region, and a bent region extending from the non-bent region and being bent, wherein the support film covers the bent region when view on the plane.

13. A display device comprising:
a display panel in which a display region and a non-display region surrounding the display region are defined;
an anti-reflective layer disposed on the display panel;
a support film in which an opening is defined when viewed on a plane, and which is disposed on an edge portion of the anti-reflective layer;
a light-shielding pattern covering an upper surface of the support film and an inner side surface of the support film defining the opening; and
a coated window disposed on the upper surface of the support film and an upper surface of the anti-reflective layer through the opening.

14. The display device of claim 13, wherein the support film comprises:
a first portion overlapping the anti-reflective layer; and
a second portion extending from the first portion, and surrounding the first portion when viewed on the plane.

15. The display device of claim 14, wherein an outer side surface of the second portion protrudes from an outer side surface of the anti-reflective layer and an outer side surface of the display panel in a direction extending away from the display region on the plane.

16. The display device of claim 15, wherein an outer side surface of the second portion and an outer side surface of the coated window are aligned with each other on a cross-section.

17. The display device of claim 14, wherein a lower surface of the first portion is higher than a lower surface of the second portion.

18. The display device of claim 17, further comprising an adhesive layer disposed between the lower surface of the first portion and an upper surface of the anti-reflective layer,
wherein a lower surface of the adhesive layer is disposed on a same plane as the lower surface of the second portion.

19. The display device of claim 14, wherein a lower surface of the first portion has the same height as a lower surface of the second portion.

20. The display device of claim 19, further comprising an adhesive layer disposed between the lower surface of the first portion and an upper surface of the anti-reflective layer,
wherein an upper surface of the adhesive layer and the lower surface of the second portion are disposed on a same plane.
